(19) United States
(12) Patent Application Publication
(10) Pub. No.: US 2009/0216442 A1
(43) Pub. Date: Aug. 27, 2009

(54) METHOD, APPARATUS AND COMPUTER PROGRAM PRODUCT FOR MAP FEATURE DETECTION

(75) Inventor: Oliver Luert, Bochum (DE)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: Nokia Corporation

(21) Appl. No.: 12/037,481

(22) Filed: Feb. 26, 2008

(51) Int. Cl. G01C 21/34; G01R 29/00

(52) U.S. Cl. 701/211; 702/57

(57) ABSTRACT

An apparatus for enabling improved map feature detection may include a processor. The processor may be configured to receive data including first signal strength information defining respective strengths of position message signals received over corresponding portions of a first position history, analyze the first signal strength information with respect to change in the respective strengths of the position message signals, and enable updating of map data with respect to a feature associated with a travel route corresponding to the first position history based on analyzing the first signal strength information. A method and computer program product for enabling improved map feature detection are also provided.

### TECHNOLOGICAL FIELD

Embodiments of the present invention relate generally to map generation technology and, more particularly, relate to a method, apparatus and computer program product for detecting features such as intersections for use, for example, in map updating and/or creation.

### BACKGROUND

The modern communications era has brought about a tremendous expansion of wireline and wireless networks. Computer networks, television networks, and telephony networks are experiencing an unprecedented technological expansion, fueled by consumer demand. Wireless and mobile networking technologies have addressed related consumer demands, while providing more flexibility and immediacy of information transfer.

Current and future networking technologies continue to facilitate ease of information transfer and convenience to users by expanding the capabilities of mobile electronic devices. One area in which there is a demand to increase ease of information transfer relates to the delivery of services to a user of a mobile terminal. The services may be in the form of a particular media or communication application desired by the user, such as a music player, a game player, an electronic book, short messages, email, content sharing, web browsing, etc. The services may also be in the form of interactive applications in which the user may respond to a network device in order to perform a task or achieve a goal. Alternatively, the network device may respond to commands or requests made by the user (e.g., content searching, mapping or routing services, etc.). The services may be provided from a network server or other network device, or even from the mobile terminal such as, for example, a mobile telephone, a mobile television, a mobile gaming system, etc.

Due to the ubiquitous nature of mobile electronic devices, people of all ages and education levels are now utilizing mobile terminals to communicate with other individuals or contacts, receive services and/or to share information, media and other content. Additionally, given recent advances in processing power, battery life, the availability of peripherals such as global positioning system (GPS) receivers and the development of various applications, mobile electronic devices are increasingly used by individuals for receiving mapping or navigation services in a mobile environment. For example, cellular telephones may be equipped with GPS and may be able to provide routing services based on existing map information and GPS data indicative of the location of the cellular telephone of a user.

Despite the great utility of enabling mobile users to utilize mapping or navigation services, a common problem related to providing such services relates to the availability and/or maintenance of maps that are up to date or current. The routine maintenance, construction, and/or development of roads or other travel routes, which may experience change on a nearly continuous basis in some regions, may make it a challenging or expensive undertaking to maintain current maps upon which to base the provision of such services. Additionally, in some remote areas, the infrequency of such changes, or the lack of demand for routine updates to maps may make the updating of such maps non-viable from an economic standpoint. Thus, the provision of good service could be expensive, while a failure to update maps may result in users developing a low opinion of the service provided.

Some developments have been made aimed at enabling the users of devices with positioning capabilities to share information that can be used to update map services. In this regard, for example, TomTom Map Share™ provides a service that enables users to manually upload changes they detect to the system. Service staff may then verify the uploaded changes for use by other service users to update their maps. This type of updating requires a relatively large amount of user input insofar as the user must manually upload data and/or manually select to enable data uploaded by others to be used for updating the user's maps. Additionally, the updating of maps based on the submitted traces may be done by aggregating data on a point by point basis to merge GPS traces. However, such aggregation typically results in a merged trace having relatively low accuracy, for example, due to GPS positioning errors. Moreover, updating maps based on submitted GPS traces only accounts for the routes actually travelled by those submitting data. Thus, certain other types of information may not be determinable by these methods. For example, traces that cross each other at an intersection may be indistinguishable from traces that cross each other at an overpass or underpass thereby reducing the value of the service with regard to updating maps for the locations of bridges, tunnels, overpasses and the like.

Accordingly, it may be desirable to provide an improved mechanism by which map data may be updated that may overcome at least some of the disadvantages described above.

### BRIEF SUMMARY

A method, apparatus and computer program product are therefore provided to enable improved map feature detection to, for example, enhance map generation. In particular, a method, apparatus and computer program product are provided that may enable the receipt of trace data defining positioning information received from a particular source. The trace data may further include information defining a signal strength of a positioning signal, e.g., GPS signal strength. Based on a change in signal strength at a particular portion of the trace data, detection of certain types of intersection features may be enhanced. For example, if a particular trace experiences a change in signal strength characterized by a reduction in signal strength followed by a subsequent increase in the signal strength, such change may be indicative of passage under a bridge corresponding to an overpass. Accordingly, for example, map generation may be improved by enabling updates with regard to features beyond merely the existence of roads, but also to features corresponding to the roads themselves.

In one exemplary embodiment, a method of enabling improved map feature detection is provided. The method may include receiving data including first signal strength information defining respective strengths of position message signals received over corresponding portions of a first position history, analyzing the first signal strength information with respect to change in the respective strengths of the position message signals, and enabling updating of map data with respect to a feature associated with a travel route corresponding to the first position history based on analyzing the first signal strength information.

In another exemplary embodiment, a computer program product for enabling improved map feature detection is provided. The computer program product includes at least one computer-readable storage medium having computer-readable program code portions stored therein. The computer-readable program code portions include first, second and third executable portions. The first executable portion is for receiving data including first signal strength information defining respective strengths of position message signals received over corresponding portions of a first position history. The second executable portion is for analyzing the first signal strength information with respect to change in the respective strengths of the position message signals. The third executable portion is for enabling updating of map data with respect to a feature associated with a travel route corresponding to the first position history based on analyzing the first signal strength information.

In another exemplary embodiment, an apparatus for enabling improved map feature detection is provided. The apparatus may include a processor. The processor may be configured to receive data including first signal strength information defining respective strengths of position message signals received over corresponding portions of a first position history, analyze the first signal strength information with respect to change in the respective strengths of the position message signals, and enable updating of map data with respect to a feature associated with a travel route corresponding to the first position history based on analyzing the first signal strength information.

In another exemplary embodiment, an apparatus for enabling improved map feature detection is provided. The apparatus includes means for receiving data including first signal strength information defining respective strengths of position message signals received over corresponding portions of a first position history, means for analyzing the first signal strength information with respect to change in the respective strengths of the position message signals, and means for enabling updating of map data with respect to a feature associated with a travel route corresponding to the first position history based on analyzing the first signal strength information.

Embodiments of the invention may provide a method, apparatus and computer program product for employment in mobile environments in which mapping or routing services are provided. As a result, for example, mobile terminal users may enjoy an improved mapping or routing service on the basis of maps that are updated using information provided automatically by other mobile terminal users.

### BRIEF DESCRIPTION OF THE SEVERAL VIEWS OF THE DRAWING(S)

Having thus described embodiments of the invention in general terms, reference will now be made to the accompanying drawings, which are not necessarily drawn to scale, and wherein:

FIG. 1 is a schematic block diagram of a mobile terminal according to an exemplary embodiment of the present invention;

FIG. 2 is a schematic block diagram of a wireless communications system according to an exemplary embodiment of the present invention;

FIG. 3 illustrates a block diagram of an apparatus for enabling improved map feature detection according to an exemplary embodiment of the present invention;

FIG. 4 illustrates a block diagram of portions of a system for enabling map feature detection according to an exemplary embodiment of the present invention;

FIG. 5 illustrates an example of a map feature that may be identified and classified according to an exemplary embodiment of the present invention;

FIG. 6A illustrates a graph of exemplary signal strength information that may be received in association with trace data corresponding to an obstruction feature according to exemplary embodiments of the present invention

FIG. 6B illustrates a graph of exemplary signal strength information that may be received in association with trace data without obstruction according to exemplary embodiments of the present invention; and

FIG. 7 is a flowchart according to an exemplary method for enabling map feature detection according to an exemplary embodiment of the present invention.

### DETAILED DESCRIPTION

Embodiments of the present invention will now be described more fully hereinafter with reference to the accompanying drawings, in which some, but not all embodiments of the invention are shown. Indeed, embodiments of the invention may be embodied in many different forms and should not be construed as limited to the embodiments set forth herein; rather, these embodiments are provided so that this disclosure will satisfy applicable legal requirements. Like reference numerals refer to like elements throughout.

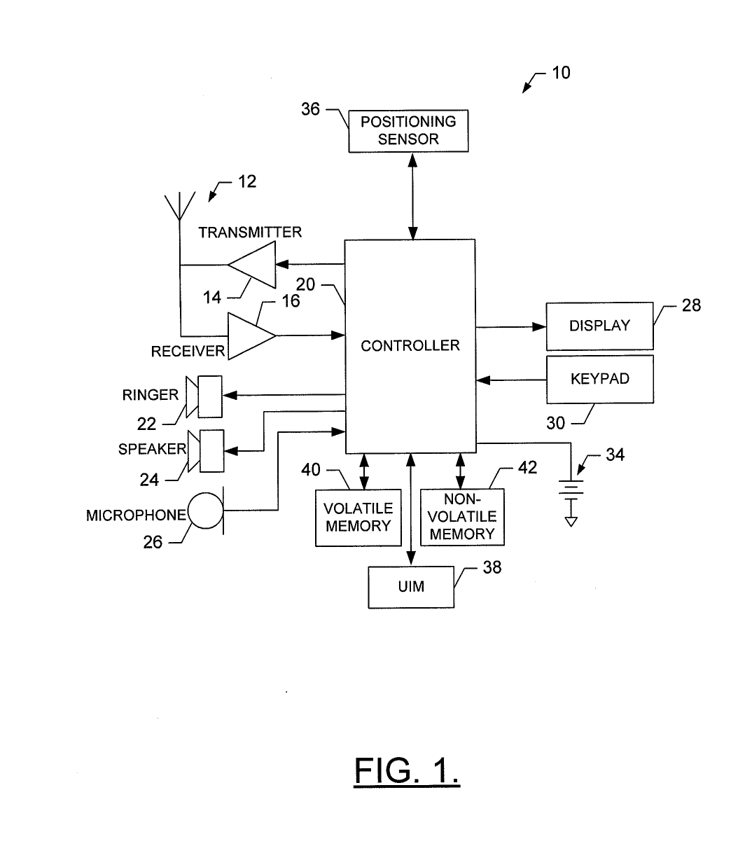

FIG. 1, one aspect of the invention, illustrates a block diagram of a mobile terminal 10 that would benefit from embodiments of the present invention. It should be understood, however, that a mobile telephone as illustrated and hereinafter described is merely illustrative of one type of mobile terminal that would benefit from embodiments of the present invention and, therefore, should not be taken to limit the scope of embodiments of the present invention. While several embodiments of the mobile terminal 10 are illustrated and will be hereinafter described for purposes of example, other types of mobile terminals, such as portable digital assistants (PDAs), pagers, mobile televisions, gaming devices, laptop computers, cameras, video recorders, audio/video player, radio, GPS devices, or any combination of the aforementioned, and other types of voice and text communications systems, can readily employ embodiments of the present invention.

In addition, while several embodiments of the method of the present invention are performed or used by a mobile terminal 10, the method may be employed by other than a mobile terminal. Moreover, the system and method of embodiments of the present invention will be primarily described in conjunction with mobile communications applications. It should be understood, however, that the system and method of embodiments of the present invention can be utilized in conjunction with a variety of other applications, both in the mobile communications industries and outside of the mobile communications industries.

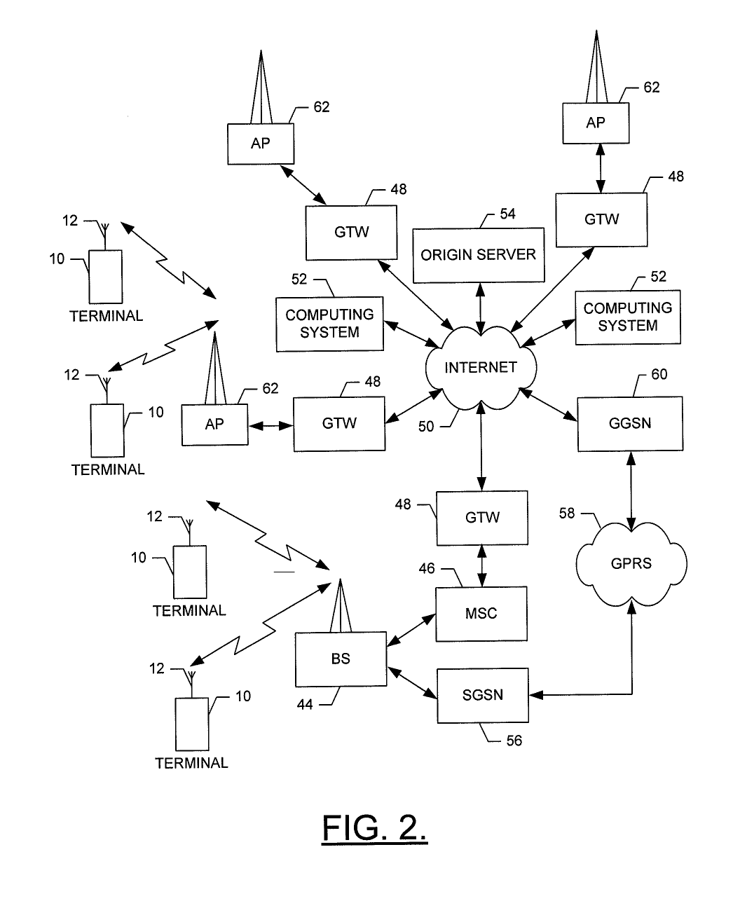

The mobile terminal 10 may include an antenna 12 (or multiple antennae) in operable communication with a transmitter 14 and a receiver 16. The mobile terminal 10 may further include an apparatus, such as a controller 20 or other processing element, that provides signals to and receives signals from the transmitter 14 and receiver 16, respectively. The signals include signaling information in accordance with the air interface standard of the applicable cellular system, and also user speech, received data and/or user generated data. In this regard, the mobile terminal 10 is capable of operating with one or more air interface standards, communication protocols, modulation types, and access types. By way of illustration, the mobile terminal 10 is capable of operating in accordance with any of a number of first, second, third and/or fourth-generation communication protocols or the like. For example, the mobile terminal 10 may be capable of operating in accordance with second-generation (2G) wireless communication protocols IS-136 (time division multiple access (TDMA)), GSM (global system for mobile communication), and IS-95 (code division multiple access (CDMA)), or with third-generation (3G) wireless communication protocols, such as Universal Mobile Telecommunications System (UMTS), CDMA2000, wideband CDMA (WCDMA) and time division-synchronous CDMA (TD-SCDMA), with fourth-generation (4G) wireless communication protocols or the like. As an alternative (or additionally), the mobile terminal 10 may be capable of operating in accordance with non-cellular communication mechanisms. For example, the mobile terminal 10 may be capable of communication in a wireless local area network (WLAN) or other communication networks described below in connection with FIG. 2.

It is understood that the apparatus, such as the controller 20, may include circuitry desirable for implementing audio and logic functions of the mobile terminal 10. For example, the controller 20 may be comprised of a digital signal processor device, a microprocessor device, and various analog to digital converters, digital to analog converters, and other support circuits. Control and signal processing functions of the mobile terminal 10 are allocated between these devices according to their respective capabilities. The controller 20 thus may also include the functionality to convolutionally encode and interleave message and data prior to modulation and transmission. The controller 20 can additionally include an internal voice coder, and may include an internal data modem. Further, the controller 20 may include functionality to operate one or more software programs, which may be stored in memory. For example, the controller 20 may be capable of operating a connectivity program, such as a conventional Web browser. The connectivity program may then allow the mobile terminal 10 to transmit and receive Web content, such as location-based content and/or other web page content, according to a Wireless Application Protocol (WAP), Hypertext Transfer Protocol (HTTP) and/or the like, for example.

The mobile terminal 10 may also comprise a user interface including an output device such as a conventional earphone or speaker 24, a ringer 22, a microphone 26, a display 28, and a user input interface, all of which are coupled to the controller 20. The user input interface, which allows the mobile terminal 10 to receive data, may include any of a number of devices allowing the mobile terminal 10 to receive data, such as a keypad 30, a touch display (not shown) or other input device. In embodiments including the keypad 30, the keypad 30 may include the conventional numeric (0-9) and related keys (#, *), and other hard and soft keys used for operating the mobile terminal 10. Alternatively, the keypad 30 may include a conventional QWERTY keypad arrangement. The keypad 30 may also include various soft keys with associated functions. In addition, or alternatively, the mobile terminal 10 may include an interface device such as a joystick or other user input interface. The mobile terminal 10 further includes a battery 34, such as a vibrating battery pack, for powering various circuits that are required to operate the mobile terminal 10, as well as optionally providing mechanical vibration as a detectable output.

In addition, the mobile terminal 10 may include a positioning sensor 36. The positioning sensor 36 may include, for example, a global positioning system (GPS) sensor, an assisted global positioning system (Assisted-GPS) sensor, a Bluetooth (BT)-GPS mouse, other GPS or positioning receivers or the like. However, in one exemplary embodiment, the positioning sensor 36 may include a pedometer or inertial sensor. In this regard, the positioning sensor 36 may be capable of determining a location of the mobile terminal 10, such as, for example, longitudinal and latitudinal directions of the mobile terminal 10, or a position relative to a reference point such as a destination or start point. Information from the positioning sensor 36 may then be communicated to a memory of the mobile terminal 10 or to another memory device to be stored as a position history or location information. In this regard, for example, the position history may define a series of data points corresponding to positions of the mobile terminal 10 at respective times. The position history may be referred to as a “trace”. The trace may further include one or more segments each of which defines a position history or route between two waypoints. In many instances, the segments may be substantially linear. However, segments could also be curvilinear to some degree.

The mobile terminal 10 may further include a user identity module (UIM) 38. The UIM 38 is typically a memory device having a processor built in. The UIM 38 may include, for example, a subscriber identity module (SIM), a universal integrated circuit card (UICC), a universal subscriber identity module (USIM), a removable user identity module (R-UIM), etc. The UIM 38 typically stores information elements related to a mobile subscriber. In addition to the UIM 38, the mobile terminal 10 may be equipped with memory. For example, the mobile terminal 10 may include volatile memory 40, such as volatile Random Access Memory (RAM) including a cache area for the temporary storage of data. The mobile terminal 10 may also include other non-volatile memory 42, which can be embedded and/or may be removable. The non-volatile memory 42 can additionally or alternatively comprise an electrically erasable programmable read only memory (EEPROM), flash memory or the like, such as that available from the SanDisk Corporation of Sunnyvale, Calif., or Lexar Media Inc. of Fremont, Calif. The memories can store any of a number of pieces of information, and data, used by the mobile terminal 10 to implement the functions of the mobile terminal 10. For example, the memories can include an identifier, such as an international mobile equipment identification (IMEI) code, capable of uniquely identifying the mobile terminal 10. Furthermore, the memories may store instructions for determining cell id information. Specifically, the memories may store an application program for execution by the controller 20, which determines an identity of the current cell, i.e., cell id identity or cell id information, with which the mobile terminal 10 is in communication. In conjunction with the positioning sensor 36, the cell id information may be used to more accurately determine a location of the mobile terminal 10.

FIG. 2 is a schematic block diagram of a wireless communications system according to an exemplary embodiment of the present invention. Referring now to FIG. 2, an illustration of one type of system that would benefit from embodiments of the present invention is provided. The system includes a plurality of network devices. As shown, one or more mobile terminals 10 may each include an antenna 12 for transmitting signals to and for receiving signals from a base site or base station (BS) 44. The base station 44 may be a part of one or more cellular or mobile networks each of which includes elements required to operate the network, such as a mobile switching center (MSC) 46. As well known to those skilled in the art, the mobile network may also be referred to as a Base Station/MSC/Interworking function (BMI). In operation, the MSC 46 is capable of routing calls to and from the mobile terminal 10 when the mobile terminal 10 is making and receiving calls. The MSC 46 can also provide a connection to landline trunks when the mobile terminal 10 is involved in a call. In addition, the MSC 46 can be capable of controlling the forwarding of messages to and from the mobile terminal 10, and can also control the forwarding of messages for the mobile terminal 10 to and from a messaging center. It should be noted that although the MSC 46 is shown in the system of FIG. 2, the MSC 46 is merely an exemplary network device and embodiments of the present invention are not limited to use in a network employing an MSC.

The MSC 46 can be coupled to a data network, such as a local area network (LAN), a metropolitan area network (MAN), and/or a wide area network (WAN). The MSC 46 can be directly coupled to the data network. In one typical embodiment, however, the MSC 46 is coupled to a gateway device (GTW) 48, and the GTW 48 is coupled to a WAN, such as the Internet 50. In turn, devices such as processing elements (e.g., personal computers, server computers or the like) can be coupled to the mobile terminal 10 via the Internet 50. For example, as explained below, the processing elements can include one or more processing elements associated with a computing system 52 (two shown in FIG. 2), origin server 54 (one shown in FIG. 2) or the like, as described below.

The BS 44 can also be coupled to a serving GPRS (General Packet Radio Service) support node (SGSN) 56. As known to those skilled in the art, the SGSN 56 is typically capable of performing functions similar to the MSC 46 for packet switched services. The SGSN 56, like the MSC 46, can be coupled to a data network, such as the Internet 50. The SGSN 56 can be directly coupled to the data network. In a more typical embodiment, however, the SGSN 56 is coupled to a packet-switched core network, such as a GPRS core network 58. The packet-switched core network is then coupled to another GTW 48, such as a gateway GPRS support node (GGSN) 60, and the GGSN 60 is coupled to the Internet 50. In addition to the GGSN 60, the packet-switched core network can also be coupled to a GTW 48. Also, the GGSN 60 can be coupled to a messaging center. In this regard, the GGSN 60 and the SGSN 56, like the MSC 46, may be capable of controlling the forwarding of messages, such as MMS messages. The GGSN 60 and SGSN 56 may also be capable of controlling the forwarding of messages for the mobile terminal 10 to and from the messaging center.

In addition, by coupling the SGSN 56 to the GPRS core network 58 and the GGSN 60, devices such as a computing system 52 and/or origin server 54 may be coupled to the mobile terminal 10 via the Internet 50, SGSN 56 and GGSN 60. In this regard, devices such as the computing system 52 and/or origin server 54 may communicate with the mobile terminal 10 across the SGSN 56, GPRS core network 58 and the GGSN 60. By directly or indirectly connecting mobile terminals 10 and the other devices (e.g., computing system 52, origin server 54, etc.) to the Internet 50, the mobile terminals 10 may communicate with the other devices and with one another, such as according to the Hypertext Transfer Protocol (HTTP) and/or the like, to thereby carry out various functions of the mobile terminals 10.

Although not every element of every possible mobile network is shown and described herein, it should be appreciated that the mobile terminal 10 may be coupled to one or more of any of a number of different networks through the BS 44. In this regard, the network(s) may be capable of supporting communication in accordance with any one or more of a number of first-generation (1G), second-generation (2G), 2.5G, third-generation (3G), 3.9G, fourth-generation (4G) mobile communication protocols or the like. For example, one or more of the network(s) can be capable of supporting communication in accordance with 2G wireless communication protocols IS-136 (TDMA), GSM, and IS-95 (CDMA). Also, for example, one or more of the network(s) can be capable of supporting communication in accordance with 2.5G wireless communication protocols GPRS, Enhanced Data GSM Environment (EDGE), or the like. Further, for example, one or more of the network(s) can be capable of supporting communication in accordance with 3G wireless communication protocols such as a UMTS network employing WCDMA radio access technology. Some narrow-band analog mobile phone service (NAMPS), as well as total access communication system (TACS), network(s) may also benefit from embodiments of the present invention, as should dual or higher mode mobile stations (e.g., digital/analog or TDMA/CDMA/analog phones).

The mobile terminal 10 can further be coupled to one or more wireless access points (APs) 62. The APs 62 may comprise access points configured to communicate with the mobile terminal 10 in accordance with techniques such as, for example, radio frequency (RF), infrared (IrDA) or any of a number of different wireless networking techniques, including WLAN techniques such as IEEE 802.11 (e.g., 802.11a, 802.11b, 802.11g, 802.11n, etc.), world interoperability for microwave access (WiMAX) techniques such as IEEE 802.16, and/or wireless Personal Area Network (WPAN) techniques such as IEEE 802.15, BlueTooth (BT), ultra wideband (UWB) and/or the like. The APs 62 may be coupled to the Internet 50. Like with the MSC 46, the APs 62 can be directly coupled to the Internet 50. In one embodiment, however, the APs 62 are indirectly coupled to the Internet 50 via a GTW 48. Furthermore, in one embodiment, the BS 44 may be considered as another AP 62. As will be appreciated, by directly or indirectly connecting the mobile terminals 10 and the computing system 52, the origin server 54, and/or any of a number of other devices, to the Internet 50, the mobile terminals 10 can communicate with one another, the computing system, etc., to thereby carry out various functions of the mobile terminals 10, such as to transmit data, content or the like to, and/or receive content, data or the like from, the computing system 52. As used herein, the terms “data,” “content,” “information” and similar terms may be used interchangeably to refer to data capable of being transmitted, received and/or stored in accordance with embodiments of the present invention. Thus, use of any such terms should not be taken to limit the spirit and scope of embodiments of the present invention.

Although not shown in FIG. 2, in addition to or in lieu of coupling the mobile terminal 10 to computing systems 52 across the Internet 50, the mobile terminal 10 and computing system 52 may be coupled to one another and communicate in accordance with, for example, RF, BT, IrDA or any of a number of different wireline or wireless communication techniques, including LAN, WLAN, WiMAX, UWB techniques and/or the like. One or more of the computing systems 52 can additionally, or alternatively, include a removable memory capable of storing content, which can thereafter be transferred to the mobile terminal 10. Further, the mobile terminal 10 can be coupled to one or more electronic devices, such as printers, digital projectors and/or other multimedia capturing, producing and/or storing devices (e.g., other terminals). Like with the computing systems 52, the mobile terminal 10 may be configured to communicate with the portable electronic devices in accordance with techniques such as, for example, RF, BT, IrDA or any of a number of different wireline or wireless communication techniques, including universal serial bus (USB), LAN, WLAN, WiMAX, UWB techniques and/or the like.

In an exemplary embodiment, content or data may be communicated over the system of FIG. 2 between a mobile terminal, which may be similar to the mobile terminal 10 of FIG. 1, and a network device of the system of FIG. 2 in order to, for example, execute applications or establish communication (for example, for purposes of content sharing) between the mobile terminal 10 and other mobile terminals. As such, it should be understood that the system of FIG. 2 need not be employed for communication between mobile terminals or between a network device and the mobile terminal, but rather FIG. 2 is merely provided for purposes of example. Furthermore, it should be understood that embodiments of the present invention may be resident on a communication device such as the mobile terminal 10, and/or may be resident on a camera, server, personal computer or other device, absent any communication with the system of FIG. 2.

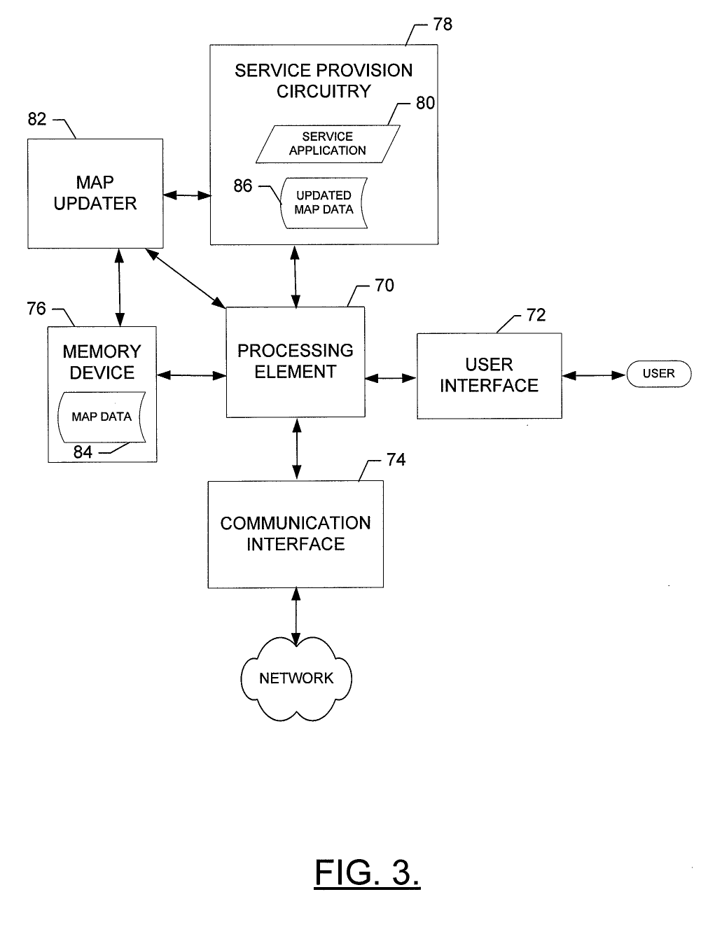

An exemplary embodiment of the invention will now be described with reference to FIG. 3, in which certain elements of an apparatus for enabling improved map feature (e.g., street intersection) detection are displayed. The apparatus of FIG. 3 may be embodied as or otherwise employed, for example, on a network device such as a server of FIG. 2. However, it should be noted that the system of FIG. 3, may also be employed on a variety of other devices, both mobile (e.g., the mobile terminal 10) and fixed, and therefore, embodiments of the present invention should not be limited to application on devices such as servers. It should also be noted that while FIG. 3 illustrates one example of a configuration of an apparatus for enabling improved map feature (e.g., street intersection) detection, numerous other configurations may also be used to implement embodiments of the present invention.

Referring now to FIG. 3, an apparatus for enabling improved map feature (e.g., street intersection) detection is provided. The apparatus may include or otherwise be in communication with a processing element 70, a user interface 72, a communication interface 74 and a memory device 76. The memory device 76 may include, for example, volatile and/or non-volatile memory (e.g., volatile memory 40 and/or non-volatile memory 42). The memory device 76 may be configured to store information, data, applications, instructions or the like for enabling the apparatus to carry out various functions in accordance with exemplary embodiments of the present invention. For example, the memory device 76 could be configured to buffer input data for processing by the processing element 70. Additionally or alternatively, the memory device 76 could be configured to store instructions for execution by the processing element 70. As yet another alternative, the memory device 76 may be one of a plurality of databases that store information in the form of static and/or dynamic information, for example, in association with a particular location, event or service point.

The processing element 70 may be embodied in a number of different ways. For example, the processing element 70 may be embodied as a processor, a coprocessor, a controller or various other processing means or devices including integrated circuits such as, for example, an ASIC (application specific integrated circuit) or FPGA (field programmable gate array). In an exemplary embodiment, the processing element 70 may be configured to execute instructions stored in the memory device 76 or otherwise accessible to the processing element 70. Meanwhile, the communication interface 74 may be embodied as any device or means embodied in either hardware, software, or a combination of hardware and software that is configured to receive and/or transmit data from/to a network and/or any other device or module in communication with the apparatus. In this regard, the communication interface 74 may include, for example, an antenna and supporting hardware and/or software for enabling communications with a wireless communication network.

The user interface 72 may be in communication with the processing element 70 to receive an indication of a user input at the user interface 72 and/or to provide an audible, visual, mechanical or other output to the user. As such, the user interface 72 may include, for example, a keyboard, a mouse, a joystick, a touch screen display, a conventional display, a microphone, a speaker, or other input/output mechanisms. In an exemplary embodiment in which the apparatus is embodied as a server, the user interface 72 may be limited, or even eliminated.

In an exemplary embodiment, the processing element 70 may be embodied as or otherwise control service provision circuitry 78. In this regard, for example, the service provision circuitry 78 may include structure for executing a service application 80. The service application 80 may be an application including instructions for execution of various functions in association with embodiments of the present invention. In an exemplary embodiment, the service application 80 may include or otherwise communicate with applications and/or circuitry for providing a mapping service. The mapping service may further include routing services and/or directory or look-up services related to particular service point (e.g., business, venue, party or event location, address, site or other entity related to a particular geographic location and/or event). As such, according to an exemplary embodiment, the processing element 70 (for example, via a map updater 82) may be configured to enable map updating with improved street intersection detection as will be described in greater detail below.

In an exemplary embodiment, the processing element 70 may also be embodied as or otherwise control the map updater 82. The map updater 82 may be any means or device embodied in hardware, software, or a combination of hardware and software that is configured to provide map updating based on received trace information from various sources. In this regard, for example, the map updater 82 may be configured to receive data from a mobile terminal defining a trace representative of a position history of the mobile terminal. The data received from the mobile terminal may further include signal strength information. In this regard, the signal strength information may indicate a relative signal strength corresponding to each position report defining a portion of the respective trace. As such, although a trace may appear to be continuous over its length, the trace may actually be comprised of a series of position reports (e.g., GPS position reports) connected to each other to define the trace. Accordingly, the map updater 82 may be configured to analyze the signal strength indications received with the trace data. More specifically, the map updater 82 may be configured to analyze changes in the signal strength indications received with the trace data.

Notably, many GPS receivers currently in use may already be capable of receiving signal strength indications corresponding to trace data. For example, NMEA (National Marine Electronics Association), which is an association that issues standards for interfacing marine electronics devices, defines standard NMEA messages to include signal strength levels with each position report. Accordingly, the map updater 82 may be configured to receive trace data defining both a series of position reports and the respective signal strength corresponding to points along the trace that correlate to each of the position reports. In particular, the map updater 82 may be configured to detect and/or analyze traces with respect to the changes or lack of changes in signal strength for the traces received.

The map updater 82 may also or alternatively be configured to merge the received trace data with other or existing trace data as described in greater detail below. The merging of trace data may verify existing map data (e.g., verifying a position of an existing road) or be used to update existing map data (e.g., by indicating a new road or route). In this regard, for example, the map updater 82 may receive information (e.g., from the memory device 76) defining map data 84 that may be pre-existing from any source. The map data 84 may define various different roads, routes, paths, or the like. In some cases the map data 84 may further include information such as terrain features, construction features, points of interest, or other map features. Data defining a road, route, path or the like may include segments and waypoints as described above. As such, the data defining a particular road, route, path, etc., may be considered an existing trace. However, a trace could alternatively only refer to position data received from a mobile terminal. Each subsequently received trace may also be merged with other or existing data to maintain a continuous, routine or periodic updating of the map data based on incoming traces. The other trace data may be trace data received from another mobile terminal (or at another time from the same or another mobile terminal) that corresponds to a currently received trace, for example, within a threshold amount.

As indicated above, at least some of the received trace data may further include signal strength information. The received signal strength information may be analyzed for changes therein, which may correspond to particular map features as described in greater detail below. As such, the received trace data (some or all of which may be merged with existing or other trace data to define composite trace information for updating the existence of travel routes on a map) may also include information related to corresponding changes in signal strength that may be used to update the map data 84 to define updated map data 86. The updated map data 86, which may be stored in the memory device 76 also, may be provided by the map updater 82 to the service provision circuitry 78 for use by the service application 80 in connection with providing mapping or routing services based on the updated map data 86. As such, the map updater 82 may generate the updated map data 86 based on the map data 84 and/or received trace data (e.g., including signal strength information) from one or more sources (e.g., mobile terminals).

In an exemplary embodiment, the map data 84 may initially represent a map acquired or purchased from an existing map vendor or otherwise generated based on data gathered (or updated) at a particular point in time. Meanwhile, the updated map data 86 may represent map data that is generated subsequent to an incorporation of user data (e.g., real life trace data) received from one or more mobile users. As such, the updated map data 86 may incorporate actual data supplied by travelers and indicative of the routes traveled by the respective travelers and corresponding signal strength information for position reports received while transiting such routes. The signal strength information may be utilized as described below to determine the location and/or type or classification of certain features related to a particular travel route. In some cases the map data 84 may itself include updated data. As such, the term “map data” may not necessarily imply that the map data has never been updated. Rather, the term “map data” should be understood to imply that there may be a more recently updated version (e.g., the updated map data 86).

In an exemplary embodiment, the trace data may be reported from users (e.g., users of the mobile terminal 10) on a continuous, periodic or routine basis. For example, in some embodiments, a mobile terminal may communicate trace information to the apparatus of FIG. 3 at predetermined intervals or in response to predetermined events (e.g., events requiring location based services). Accordingly, at the predetermined interval or in response to an occurrence of the predetermined event, the mobile terminal may upload trace information including trace data for one or more travel segments to the apparatus. As yet another alternative, a mobile terminal may report a continuous or near continuous stream of position information to the apparatus in a real-time or nearly real-time manner. Combinations of the above described mechanisms, or operation in accordance with selectable modes defining one or more of the above or other possible mechanisms may also be employed.

Although in some embodiments, the user may be prompted to release trace data to the apparatus or the trace data may only be received by the apparatus in response to the user voluntarily sending such data to the apparatus via an overt action, the trace data may also be acquired automatically. For example, participants in a service (e.g., a mapping or routing service) may consent to sharing their information under all or predetermined circumstances for the common good of other users in updating the map data 84. As another alternative, users may enable or disable trace and/or signal strength reporting functions and, when such functions are enabled, the reporting of trace and signal strength data to the apparatus may be performed from the mobile terminal 10 of the respective user who enabled such functionality without further user interaction. Accordingly, data for updating map data may be acquired without significant (or in some circumstances any) user interaction. In some instances, a user may provide a profile during registration for a service associated with providing map updates. The profile may define the timing of and/or circumstances under which the user's respective terminal reports trace data and the corresponding signal strength information to the apparatus. Accordingly, reporting of trace data and the corresponding signal strength information to the apparatus may be accomplished without additional user interaction at the time such reports are made.

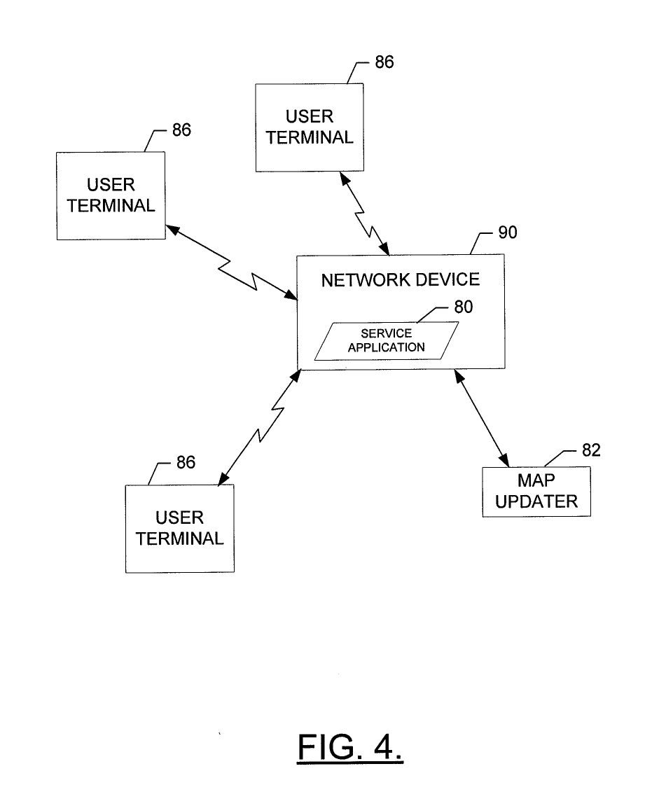

FIG. 4 illustrates an embodiment of the present invention in which certain elements of a system for enabling improved map feature (e.g., street intersection) detection are displayed. The system of FIG. 4 may be employed in connection with the mobile terminal 10 of FIG. 1 (or a plurality of mobile terminals) and/or the network illustrated in reference to FIG. 2. However, although FIG. 4 illustrates an embodiment of the present invention being practiced in connection with a network device 90 (e.g., a server) that coordinates functionality associated with practicing embodiments of the invention in combination with other devices, it should be noted that the system of FIG. 4 may also be employed on a variety of other devices, both mobile and fixed, and therefore, embodiments of the present invention should not be limited to application on devices such as servers or in combination with the specific devices illustrated in FIG. 4. As such, it should be appreciated that while FIG. 4 illustrates one example of a configuration of a system for enabling improved map feature detection, numerous other configurations may also be used to implement embodiments of the present invention. Accordingly, the devices or elements described below may not be mandatory and thus some may be omitted in certain embodiments. Moreover, embodiments of the present invention need not be practiced at a single device, but rather combinations of devices may collaborate to perform embodiments of the present invention.

Referring now to FIG. 4, a system for enabling improved map feature detection is provided. The system may include the network device 90 (e.g., the apparatus of FIG. 3), which may be in communication with one or more user terminals 92 (e.g., via the system of FIG. 2), each of which may be any of the exemplary mobile terminal devices described in connection with the description of FIG. 1 (e.g., a GPS device or GPS enabled mobile phone, etc.). The network node 90, which may execute the service application 80, may utilize the map updater 82 to determine information about features related to a particular route based on trace data (e.g., including corresponding signal strength information) received from each of the user terminals 92 with existing or other trace or map data to provide map updating so that mapping and/or routing services may be provided on the basis of updated map data. The map updater 82 may be collocated with or a component of the network device 90. However, as an alternative, the map updater 82 may be located at another device in communication with the network device 90 as shown, for example, in FIG. 4.

As indicated above, the reporting or provision of trace data and therefore also signal strength information from the various user terminals 92 may be provided in an automatic (or semi-automatic) fashion. As such, the updating of the map data, and thus map generation, may be automatically (or semi-automatically) performed. In this regard, for example, existing maps may be updated to define new roads, bridges, overpasses, tunnels, detours, intersections, paths, etc. and/or new maps may be produced (e.g., for emerging markets) based on trace data indicative of routes, paths, roads, bridges, overpasses, tunnels, etc., that have been traveled by individuals carrying user terminals 92. In either case, whether an existing map is generated or a new map is generated, map generation based on utilizing signal strength information may be considered an enabling factor with respect to providing certain features of the maps generated. The map updater 82 may be configured to perform updates in response to any desirable stimulus. For example, the map updater 82 may be configured to perform updates in response to receipt of a new trace, in response to other predefined events, or in response to passage of a predetermined time period since the last update.

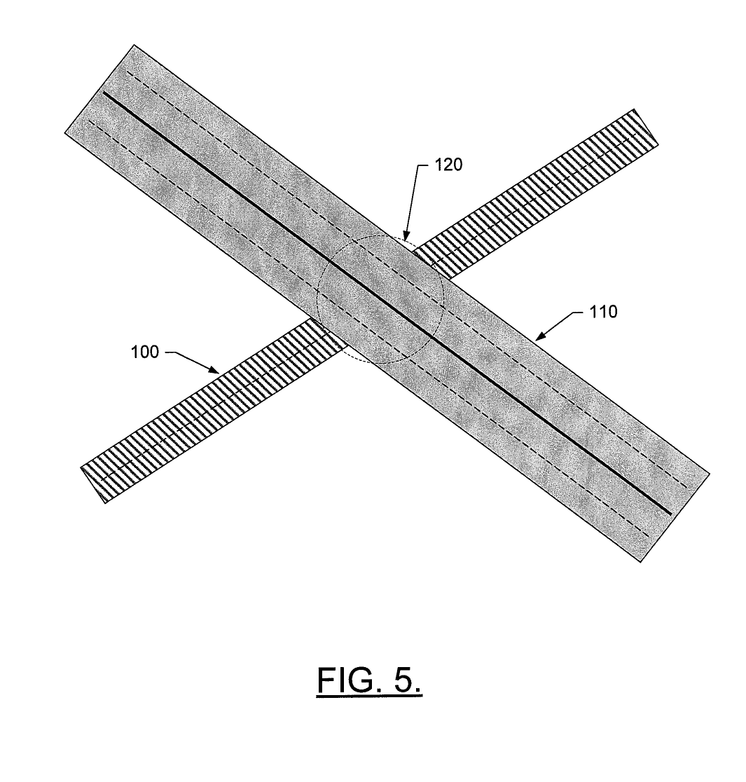

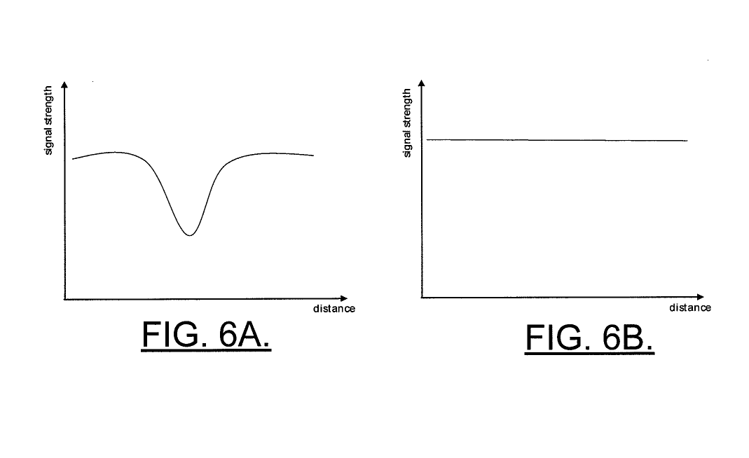

A more detailed description of the operation of the map updater 82 will now be described in reference to FIGS. 5 and 6, which illustrate examples of intersection detection in accordance with exemplary embodiments of the present invention. In this regard, FIG. 5 illustrates an example of a map related feature that may be determined in accordance with an exemplary embodiment of the present invention. As shown in FIG. 5, a first road 100 may be defined based on existing map data and/or the merging of received trace data. In reality, the first road 100 may pass underneath a second road 110 (as shown in FIG. 5). The second road 110 may also be defined based on existing map data and/or the merging of received trace data. In this regard, for example, the second road 110 may include a bridge, trestle or the like spanning the first road 100 and defining an overpass over a portion of the first road 100. As such, portion 120 may generally correspond to a portion of the second road 110 that may obstruct data positioning signals received while beneath the second road 110 and transiting on the first road 100. Thus, the signal strength of positioning messages received at a mobile terminal or other device with a GPS or other positioning receiver that is passing through the portion 120 on the first road 100 may be expected to decrease for the period of time that the device is under the second road 110 and increase thereafter.

Embodiments of the present invention may be useful in situations where, for example, the situation of FIG. 5 represents a change from a previous condition indicated on an existing map. For example, if the first and second roads 100 and 110 previously intersected one another, but a construction project changed the traffic situation to define an overpass situation instead of an intersection, embodiments of the present invention may be utilized to update the existing map. As yet another possibility, in an emerging market, or in an area where new construction is underway, trace merging with respect to trace data reported from mobile terminals of travelers transiting the first and second roads 100 and 110 may be utilized to define a potential intersection of the first and second roads 100 and 110 at the defined portion 120, and embodiments of the present invention may be utilized to determine whether the potential intersection is, for example, an overpass or an intersection. As such, embodiments of the present invention may be utilized to determine the existence and classification of various features that may be included in the updated map data 86. Embodiments of the present invention may also confirm existing maps instead of only finding applicability in the generation of new or updated maps.

In any case, embodiments of the present invention may utilize signal strength information related to trace data to detect and classify intersections and/or other crossings or features that may cause an obstruction to the signal strength of positioning messages (or indicate an absence of such obstruction). In this regard, for example, the map updater 82 may be configured to receive the signal strength information (which may be stored and thereafter reported by a mobile terminal to the network device 90 along with trace data) and, based on changes in the signal strength information, determine whether a particular intersection corresponds to a bridge or overpass situation. Operation of the map updater 82 in this regard may be further understood in relation to the description below referring to FIG. 6.

FIG. 6, which includes FIG. 6A and FIG. 6B, illustrates graphs of exemplary signal strength information that may be received in association with trace data according to exemplary embodiments of the present invention. In this regard, the graphs of FIGS. 6A and 6B each illustrate signal strength plotted against distance. The distance may correspond to the distance covered over a portion of a trace (e.g., a segment such as the portion of either the first road 100 or the second road I 10 that is shown in FIG. 5). As such, the graph of FIG. 6B may be considered to be illustrative of a situation in which the device receiving positioning data (e.g., GPS positioning messages) does not pass under an object that may obstruct the signals carrying such data from reaching the device. Meanwhile, the graph of FIG. 6A may be considered illustrative of a situation in which the device receiving positioning data (e.g., GPS positioning messages) passes under an object that may obstruct the signals carrying such data from reaching the device, thereby causing the noticeable temporary reduction in signal strength for the period during which the obstruction occurred. Accordingly, for example, the graph of FIG. 6A may be assumed to correspond to at least one trace received from a device transiting the first road 100 and the graph of FIG. 6B may be assumed to correspond to at least one trace received from a device transiting the second road 110.

The map updater 82 may be configured to analyze changes in the signal strength received for a particular trace to determine whether an intersection occurs (e.g., whether the roads intersect each other on the same level so that traffic crosses portions of shared roadway) or whether an overpass, bridge, trestle, tunnel, or the like is present such that, although the traces may intersect, the corresponding roads do not. In this regard, a change in signal strength above a threshold amount for a particular region may correspond to an obstruction of the signal that may correlate to a road obstruction or crossing such as a bridge, overpass, trestle, tunnel, or the like. Further, a change indicative of a road obstruction or crossing of the kind described above may be characterized by a relatively rapid decrease in signal strength followed by a corresponding relatively rapid increase in signal strength to a level similar to the level prior to the change. As such, change indicative of a road obstruction or crossing of the kind described above may typically be a momentary signal strength reduction. Accordingly, the map updater 82 may be configured to identify signal strength changes of a threshold magnitude, which have a corresponding increase in signal strength of substantially similar size to a preceding decrease in signal strength over a given period of time (e.g., a threshold rate of reduction and restoration). In other words, in order to be characterized by the map updater 82 as an event corresponding to a road obstruction or crossing situation of the kind described above, the signal strength of a particular trace may decrease by a threshold amount and return to substantially same signal strength (e.g., to within a threshold value from some preferred amount or percentage of a prior value (or prior time averaged value)) that was measured before the decrease within a specified time period thereby defining a threshold rate of reduction and restoration of the signal strength.

The map updater 82 may also be configured to consider a period of time during which signal strength values are decreased and device speed in making determinations. In this regard, the period of time during which signal strength values are decreased (and in some cases also the magnitude of the decrease) may, in some instances, be indicative of the type of feature associated with causing the decrease. Rate of motion or speed of the device reporting the signal strength changes may also impact such indications. For example, a relatively short reduction and restoration period may typically be indicative of an overpass situation, while a relatively longer reduction and restoration period may be indicative of a tunnel or a situation where one road passes beneath another road for a period of time. However, if the device reporting the signal strength changes is traveling relatively slowly, the reduction and restoration period may actually be longer than would normally be expected. As such, by considering the vehicle speed, even the longer reduction and restoration period may be recognized by the map updater 82 to correlate to an overpass instead of a tunnel.

Notably, the map updater 82 may be configured to respond to changes in signal strength rather than to the magnitude of the signal strength itself. As such, the map updater 82 is less likely to be impacted by situations that may cause a general reduction in signal strength for an entire region or period of time. For example, certain environmental conditions, weather conditions, satellite positions, etc., may cause reductions in signal strength for a corresponding time period or region. However, such a decrease would likely either occur relatively slowly or last for a relatively long time. Accordingly, for example, even if a rain squall was encountered in which signal strength decreased rapidly and, after a minute or two, subsequently increased rapidly to the same level encountered before entering the squall, such change may not occur within the specified time period required to define a reduction and restoration of signal strength that exceeds (or is below) the corresponding threshold.

In some embodiments, the map updater 82 may analyze signal strength information for both traces in the case of intersecting traces. In this regard, if the signal strength for one of the traces remains relatively constant, while the signal strength of the other of the traces experiences a negative change (and/or a negative followed by a positive change), then the map updater 82 may classify the crossing as non-intersecting (e.g., indicative of a bridge or overpass). Meanwhile, if both traces have signal strengths that are relatively constant through the intersection of the traces, then the map updater 82 may classify the crossing as an intersection. Accordingly, the map updater 82 may not only detect or verify non-intersecting situations, but also intersecting situations for either generating an updated or initial map for a particular area.

The map updater 82 may operate in this capacity in various different ways. For example, the map updater 82 may be configured to analyze signal strength information for only those portions of trace data that are proximate to a trace intersection. In other words, the map updater 82 may be configured to analyze trace data that is received and correlates to a portion of one trace that intersects (or is within a threshold distance of) another trace. Intersections of traces may be defined as any traces which are not correlated to the same road, but which intersect or cross each other at some point along the respective traces. In some instances a minimum angle of intersection may be defined for considering traces to be intersecting, but such a minimum angle is not necessary in all situations. In fact, some portions of one road may lie completely under a corresponding portion of another road with a minimal angle of intersection at either end of the corresponding portions.

As an alternative, the map updater 82 may operate in response to operator initiation over defined portions of one or more roads. For example, an operator may select a particular road (or portion of the road) and all or at least a predefined set (which could be as small as one) of traces that correspond to the particular road (or portion) may be analyzed with respect to determining whether any intersecting traces correspond to intersections instead of non-intersecting road crossings (e.g., bridges, trestles, tunnels, or the like). Alternatively, the operator may define one or more particular intersections for which corresponding signal strength information may be analyzed.

In other embodiments, all data for a particular road, route, device, trace, geographical area, or other defined data set may be analyzed over a given defined period. As such, for example, data for a specific area and/or for a specific time period may be analyzed for intersection determinations in accordance with embodiments of the present invention. Thus, embodiments of the present invention need not only be used for analyzing intersections between roads and thus need not analyze more than one trace. Rather, embodiments of the present invention may also be used to analyze trace data for a single trace in order to detect tunnels or other passages that may provide signal obstruction that are not related to crossings with other roads or rail lines.

In an exemplary embodiment, the map updater 82 may not be configured to simply update the map data 84 to produce the updated map data 86 in response to a single detection of trace data corresponding to signal strength having at least a threshold rate of reduction and restoration of signal strength. In this regard, for example, signal strength reduction may not always occur in every crossing situation if the bridge is particularly high or particularly narrow. Additionally, there may be certain random situations that may provide an obstruction for a temporary time period, but may not correspond to a road crossing situation or a tunnel. Accordingly, embodiments of the present invention may be designed such that a threshold number of detections of trace data corresponding to signal strength having at least the threshold rate of reduction and restoration of signal strength may be required prior to a particular intersection or portion of a road qualifying for updating by the map updater 82. Alternatively, receipt of a threshold percentage of traces corresponding to a particular location and having the threshold rate of reduction and restoration of signal strength may trigger updating of the map data by the map updater 82. As yet another alternative, an operator may decide to initiate an update based on a review of received data and such update may be triggered by an operator initiation.

Furthermore, in order to practice embodiments of the present invention, mobile terminals may store signal strength information in association with trace data, thereby consuming more resources. As such, some embodiments may be configured to enable mobile terminal users to define rules for or otherwise enable storage and reporting features as well as updating features in order to permit the mobile terminal to communicate with a network device to share information for use in updating as well as to received information regarding such updates from the network device.

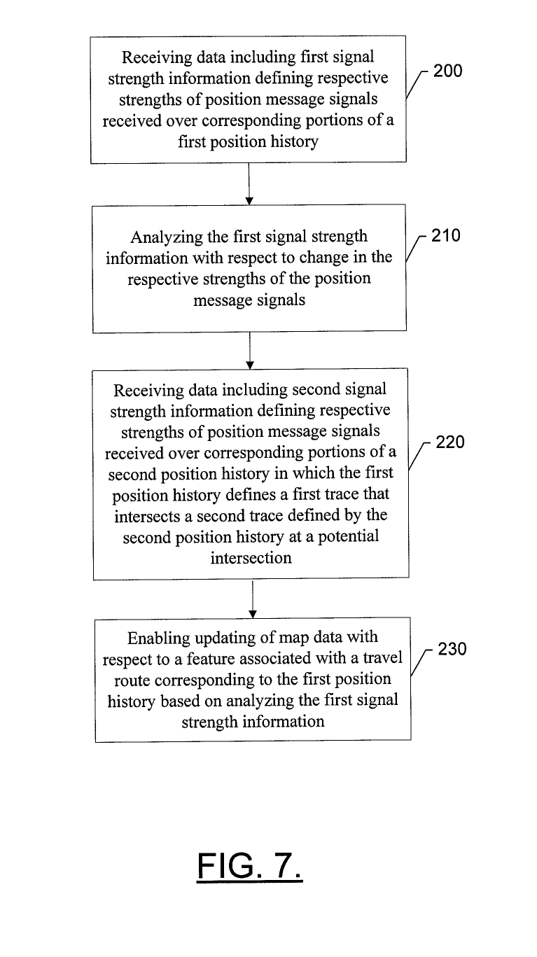

FIG. 7 is a flowchart of a system, method and program product according to exemplary embodiments of the invention. It will be understood that each block or step of the flowcharts, and combinations of blocks in the flowcharts, can be implemented by various means, such as hardware, firmware, and/or software including one or more computer program instructions. For example, one or more of the procedures described above may be embodied by computer program instructions. In this regard, the computer program instructions which embody the procedures described above may be stored by a memory device of the mobile terminal or network device and executed by a built-in processor in the mobile terminal or network device. As will be appreciated, any such computer program instructions may be loaded onto a computer or other programmable apparatus (i.e., hardware) to produce a machine, such that the instructions which execute on the computer or other programmable apparatus create means for implementing the functions specified in the flowcharts block(s) or step(s). These computer program instructions may also be stored in a computer-readable memory that can direct a computer or other programmable apparatus to function in a particular manner, such that the instructions stored in the computer-readable memory produce an article of manufacture including instruction means which implement the function specified in the flowcharts block(s) or step(s). The computer program instructions may also be loaded onto a computer or other programmable apparatus to cause a series of operational steps to be performed on the computer or other programmable apparatus to produce a computer-implemented process such that the instructions which execute on the computer or other programmable apparatus provide steps for implementing the functions specified in the flowcharts block(s) or step(s).

Accordingly, blocks or steps of the flowcharts support combinations of means for performing the specified functions, combinations of steps for performing the specified functions and program instruction means for performing the specified functions. It will also be understood that one or more blocks or steps of the flowcharts, and combinations of blocks or steps in the flowcharts, can be implemented by special purpose hardware-based computer systems which perform the specified functions or steps, or combinations of special purpose hardware and computer instructions.

In this regard, one embodiment of a method for enabling map feature detection as illustrated, for example, in FIG. 7 may include receiving data including first signal strength information defining respective strengths of position message signals received over corresponding portions of a first position history at operation 200. Operation 210 may include analyzing the first signal strength information with respect to change in the respective strengths of the position message signals. In some embodiments, an optional operation 220 may include receiving data including second signal strength information defining respective strengths of position message signals received over corresponding portions of a second position history in which the first position history defines a first trace that intersects a second trace defined by the second position history at a potential intersection. The method may further include enabling updating of map data with respect to a feature associated with a travel route corresponding to the first position history based on the analysis at operation 230. In this regard, if changes of a certain type or degree are determined by the analysis, such changes may be associated with corresponding types of features that may be indicated on a map and the map data may be updated to reflect the corresponding feature or features to be added to the map. The updating of map data may be used in connection with generation of new maps (e.g., by determining features to be added with other map data (thereby updating such data) for the creation of a new map) or for the updating of existing maps (e.g., by determining changes to existing features or additional features to be added to an existing map).

In an exemplary embodiment, operation 210 may include determining whether the first signal strength information is indicative of a reduction and subsequent restoration of signal strength at a particular portion of the travel route. Such determination may further include determining whether the first signal strength information is indicative of a threshold rate of reduction and subsequent restoration of signal strength in some embodiments. Operation 230 may further include associating a signal obstructing feature with the particular portion of the travel route.

In some embodiments, operation 230 may include updating the map data with respect to the feature associated with the travel route corresponding to the first position history in response to the first signal strength information indicating a reduction and subsequent restoration of signal strength proximate to the potential intersection and the second signal strength information indicating substantially no change in respective signal strengths. Alternatively or additionally, operation 230 may include enabling generation of a change to existing map data indicative of a particular type of crossing associated with the potential intersection defining a relationship between the travel route corresponding to the first position history and a travel route corresponding to the second position history. In some situations receiving data including the first signal strength information may include receiving reports from a mobile terminal defining respective strengths of position message signals received at the mobile terminal during travel over corresponding portions of the first position history.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. A method comprising:
receiving data including first signal strength information defining respective strengths of position message signals received over corresponding portions of a first position history;
analyzing the first signal strength information with respect to change in the respective strengths of the position message signals; and
enabling updating of map data with respect to a feature associated with a travel route corresponding to the first position history based on analyzing the first signal strength information.

2. A method according to claim 1, wherein analyzing the first signal strength information with respect to change comprises determining whether the first signal strength information is indicative of a reduction and subsequent restoration of signal strength at a particular portion of the travel route and wherein updating of the map data comprises associating a signal obstructing feature with the particular portion of the travel route.

3. A method according to claim 2, wherein determining whether the first signal strength information is indicative of the reduction and subsequent restoration of signal strength at the particular portion of the travel route further comprises determining whether the first signal strength information is indicative of a threshold rate of reduction and subsequent restoration of signal strength.

4. A method according to claim 2, further comprising receiving data including second signal strength information defining respective strengths of position message signals received over corresponding portions of a second position history in which the first position history defines a first trace that intersects a second trace defined by the second position history at a potential intersection.

5. A method according to claim 4, wherein enabling updating of the map data further comprises updating the map data with respect to the feature associated with the travel route corresponding to the first position history in response to the first signal strength information indicating a reduction and subsequent restoration of signal strength proximate to the potential intersection and the second signal strength information indicating substantially no change in respective signal strengths.

6. A method according to claim 4, wherein enabling updating of the map data with respect to the feature associated with the travel route comprises enabling generation of a change to existing map data indicative of a particular type of crossing associated with the potential intersection defining a relationship between the travel route corresponding to the first position history and a travel route corresponding to the second position history.

7. A method according to claim 1, wherein receiving data including the first signal strength information comprises receiving reports from a mobile terminal defining respective strengths of position message signals received at the mobile terminal during travel over corresponding portions of the first position history.

8. A computer program product comprising at least one computer-readable storage medium having computer-readable program code portions stored therein, the computer-readable program code portions comprising:
a first executable portion for receiving data including first signal strength information defining respective strengths of position message signals received over corresponding portions of a first position history;
a second executable portion for analyzing the first signal strength information with respect to change in the respective strengths of the position message signals; and
a third executable portion for enabling updating of map data with respect to a feature associated with a travel route corresponding to the first position history based on analyzing the first signal strength information.

9. A computer program product according to claim 8, wherein the second executable portion includes instructions for determining whether the first signal strength information is indicative of a reduction and subsequent restoration of signal strength at a particular portion of the travel route and wherein the third executable portion includes instructions for associating a signal obstructing feature with the particular portion of the travel route.

10. A computer program product according to claim 9, wherein the second executable portion includes instructions for determining whether the first signal strength information is indicative of a threshold rate of reduction and subsequent restoration of signal strength.

11. A computer program product according to claim 9, further comprising a fourth executable portion for receiving data including second signal strength information defining respective strengths of position message signals received over corresponding portions of a second position history in which the first position history defines a first trace that intersects a second trace defined by the second position history at a potential intersection.

12. A computer program product according to claim 11, wherein the third executable portion includes instructions for updating the map data with respect to the feature associated with the travel route corresponding to the first position history in response to the first signal strength information indicating a reduction and subsequent restoration of signal strength proximate to the potential intersection and the second signal strength information indicating substantially no change in respective signal strengths.

13. A computer program product according to claim 11, wherein the third executable portion includes instructions for enabling generation of a change to existing map data indicative of a particular type of crossing associated with the potential intersection defining a relationship between the travel route corresponding to the first position history and a travel route corresponding to the second position history.

14. A computer program product according to claim 8, wherein the first executable portion includes instructions for receiving reports from a mobile terminal defining respective strengths of position message signals received at the mobile terminal during travel over corresponding portions of the first position history.

15. An apparatus comprising a processor configured to:
receive data including first signal strength information defining respective strengths of position message signals received over corresponding portions of a first position history;
analyze the first signal strength information with respect to change in the respective strengths of the position message signals; and
enable updating of map data with respect to a feature associated with a travel route corresponding to the first position history based on analyzing the first signal strength information.

16. An apparatus according to claim 15, wherein the processor is configured to analyze the first signal strength information with respect to change by determining whether the first signal strength information is indicative of a reduction and subsequent restoration of signal strength at a particular portion of the travel route and wherein the processor is configured to update of the map data by associating a signal obstructing feature with the particular portion of the travel route.

17. An apparatus according to claim 16, wherein the processor is configured to determine whether the first signal strength information is indicative of the reduction and subsequent restoration of signal strength at the particular portion of the travel route further by determining whether the first signal strength information is indicative of a threshold rate of reduction and subsequent restoration of signal strength.

18. An apparatus according to claim 16, wherein the processor is configured to receive data including second signal strength information defining respective strengths of position message signals received over corresponding portions of a second position history in which the first position history defines a first trace that intersects a second trace defined by the second position history at a potential intersection.

19. An apparatus according to claim 18, wherein the processor is configured to enable updating of the map data by updating the map data with respect to the feature associated with the travel route corresponding to the first position history in response to the first signal strength information indicating a reduction and subsequent restoration of signal strength proximate to the potential intersection and the second signal strength information indicating substantially no change in respective signal strengths.

20. An apparatus according to claim 18, wherein the processor is configured to enable updating of the map data with respect to the feature associated with the travel route by enabling generation of a change to existing map data indicative of a particular type of crossing associated with the potential intersection defining a relationship between the travel route corresponding to the first position history and a travel route corresponding to the second position history.

21. An apparatus according to claim 15, wherein the processor is configured to receive reports from a mobile terminal defining respective strengths of position message signals received at the mobile terminal during travel over corresponding portions of the first position history.

22. An apparatus comprising:
means for receiving data including first signal strength information defining respective strengths of position message signals received over corresponding portions of a first position history;
means for analyzing the first signal strength information with respect to change in the respective strengths of the position message signals; and
means for enabling updating of map data with respect to a feature associated with a travel route corresponding to the first position history based on analyzing the first signal strength information.

23. An apparatus according to claim 22, wherein means for analyzing further comprises means for determining whether the first signal strength information is indicative of a reduction and subsequent restoration of signal strength at a particular portion of the travel route and wherein updating of the map data comprises associating a signal obstructing feature with the particular portion of the travel route.
